(19) United States
(12) Patent Application Publication
(10) Pub. No.: US 2025/0152980 A1
(43) Pub. Date: May 15, 2025

(54) FIRE EXTINGUISHING DEVICE, CHARGE/DISCHARGE INSPECTION DEVICE HAVING THE SAME, AND FIRE EXTINGUISHING METHOD

(71) Applicant: NIPPON STEEL TEXENG. CO., LTD., Tokyo (JP)

(72) Inventors: Tomoki HARAGUCHI, Tokyo (JP); Teruhito ISHIBASHI, Tokyo (JP)

(21) Appl. No.: 19/023,109

(22) Filed: Jan. 15, 2025

Related U.S. Application Data
(63) Continuation of application No. PCT/JP2023/029868, filed on Aug. 18, 2023.

(30) Foreign Application Priority Data
Aug. 23, 2022 (JP) 2022-132854

(51) Int. Cl. A62C 3/16; G01R 31/36; H01M 50/673

(52) U.S. Cl. CPC A62C 3/16; G01R 31/3644; H01M 50/673

(57) ABSTRACT

Provided are a fire extinguishing device and the like capable of realizing a quick fire extinguishing function without requiring a tank for submerging secondary batteries and with a simple structure. A fire extinguishing device includes: a plate on which one or more secondary batteries are placed; an enclosure provided so as to surround four sides of the secondary batteries placed on the plate; a lifting and lowering part that lifts or lowers the plate or the enclosure to bring the plate and the enclosure into close contact with each other; and a supply part that supplies a fire extinguishing agent to an area formed by the plate and the enclosure.

### CROSS-REFERENCE TO RELATED APPLICATIONS

This application is a Continuation Application of PCT application No. PCT/JP2023/029868 filed on Aug. 18, 2023, which is based upon and claims priority to Japanese Patent Application No. JP2022-132854 filed on Aug. 23, 2022, the disclosures of which are incorporated by reference.

### TECHNICAL FIELD

The present invention relates to a fire extinguishing device for extinguishing a fire that occurs in a secondary battery, a charge/discharge inspection device using the same, and a fire extinguishing method.

### BACKGROUND ART

Conventional techniques for extinguishing a fire that occurs in a secondary battery include the ones described in, for example, Patent Literatures 1 and 2.

Patent Literature 1 describes a secondary battery transport tray for housing and transporting a plurality of battery trays in each of which a plurality of secondary batteries are arranged in the thickness direction. Further, this secondary battery transport tray has a lid that closes the openings watertightly when water is stored in the secondary battery transport tray.

In addition, Patent Literature 1 describes that with this configuration, when a secondary battery generates excessive heat or catches fire, water is supplied to the secondary battery transport tray to simultaneously submerge a large number of secondary batteries, thereby enabling cooling or fire extinguishment in a short period of time.

On the other hand, Patent Literature 2 describes battery charge/discharge equipment equipped with a fire extinguishing device for extinguishing a fire in a battery, and a method for extinguishing a fire in the battery charge/discharge equipment. Further, in this battery charge/discharge equipment, fire detection sensors are disposed on each test shelf to which batteries are transported by a stacker crane, the stacker crane is provided with a primary fire extinguisher of a gas injection type, and one of the test shelves is provided with a submersion tank.

In addition, Patent Literature 2 describes that when a fire in a battery is detected by a fire detection sensor, fire extinguishment is performed using the primary fire extinguisher, and if the fire in the battery is not extinguished even after using the primary fire extinguisher, the stacker crane is used to transport the battery to the submersion tank where secondary fire extinguishment is performed.

### CITATION LIST

### Patent Literature

Patent Literature 1: Japanese Patent No. 6741308
Patent Literature 2: Japanese Patent No. 5595332

### SUMMARY OF INVENTION

### Technical Problem

However, since the secondary battery transport tray described in Patent Literature 1 is for housing and transporting a plurality of battery trays in each of which a plurality of secondary batteries are disposed, the weight of objects to be transported is naturally large and high transport capacity is required. Further, when water is stored in this secondary battery transport tray, the plurality of openings need to be closed watertightly (FIG. 1 of Patent Literature 1), and therefore the structure may become complex or it may take time to start extinguishing a fire.

Further, the battery charge/discharge equipment described in Patent Literature 2 requires that the submersion tank be provided in one of the test shelves by allowing some space, and that the batteries be transported using a stacker crane, and therefore similarly the structure may become complex and it may take time to start extinguishing a fire.

Therefore, the present invention provides a fire extinguishing device capable of realizing a quick fire extinguishing function without requiring a tank for submerging secondary batteries and with a simple structure, a charge/discharge inspection device having the same, and a fire extinguishing method.

### Solution to Problem

A fire extinguishing device of the present invention includes: a plate on which one or more secondary batteries are placed; an enclosure provided so as to surround four sides of the secondary batteries placed on the plate; a lifting and lowering part that lifts or lowers the plate or the enclosure to bring the plate and the enclosure into close contact with each other; and a supply part that supplies a fire extinguishing agent to an area formed by the plate and the enclosure.

As a result, the plate or the enclosure is lifted or lowered, so that they come into close contact with each other, and therefore the secondary batteries placed on the plate are housed in the area defined by the plate and the enclosure. Then, the fire extinguishing agent is supplied into the area by the supply part.

Here, it is desirable that the enclosure is provided so as to surround four sides and an upper side of the secondary batteries placed on the plate, and a part of the enclosure or the plate has an opening from which the fire extinguishing agent is injected.

This makes it possible to cover not only the four sides but also the upper side of the secondary batteries placed on the plate. In addition, even if the upper side of the secondary batteries are also covered, the fire extinguishing agent is supplied into the area from the opening.

Further, it is desirable that the fire extinguishing device further includes a pressurizing part that is provided so as to be housed in the area and pressurizes the secondary batteries located in the area toward an outside of the area.

This enables the secondary batteries located in the area to be pressurized toward the outside of the area.

Further, a configuration is desirable in which the fire extinguishing device further includes a container that transports one secondary battery or a plurality of secondary batteries arranged in a thickness direction, wherein the container is placed on the plate.

As a result, the secondary batteries that are housed in the container and transported can be placed on the plate as they are (while housed in the container).

Further, it is desirable that the fire extinguishing agent is a liquid, and the fire extinguishing device further includes a pan provided below the plate for receiving the liquid overflowing from the area.

As a result, even if the fire extinguishing agent that is a liquid supplied from the supply part (e.g. water) overflows from the area, the pan can receive the water.

Note that a charge/discharge inspection device of the present invention includes: these fire extinguishing devices; a probe unit to be connected to a secondary battery; and a lifting and lowering part that lifts or lowers the plate or the probe unit to connect the secondary battery and the probe unit to each other.

This makes it possible to lift or lower the plate or the probe unit to connect the secondary battery and the probe unit or conversely disconnect them, thereby enabling a charge/discharge inspection in a configuration equipped with a fire extinguishing device.

In particular, it is desirable that the charge/discharge inspection device further includes a cooling part that is provided on top of the plate and cools the secondary battery from below.

This enables the cooling part to cool the secondary battery placed on the plate from below.

On the other hand, a fire extinguishing method of the present invention includes: a step of placing one or more secondary batteries on a plate; a step of lowering an enclosure provided so as to surround four sides of the secondary batteries placed on the plate or lifting the plate to bring the plate and the enclosure into close contact with each other; and a step of supplying a fire extinguishing agent from an opening to an area formed by the plate and the enclosure.

### Advantageous Effects of Invention

(1) With a configuration in which the fire extinguishing device of the present invention includes: a plate on which one or more secondary batteries are placed; an enclosure provided so as to surround four sides of the secondary batteries placed on the plate; a lifting and lowering part that lifts or lowers the plate or the enclosure to bring the plate and the enclosure into close contact with each other; and a supply part that supplies a fire extinguishing agent to an area formed by the plate and the enclosure, the plate or the enclosure is lifted or lowered, so that they come into close contact with each other, and therefore the secondary batteries are housed in the area defined by the plate and the enclosure. Then, since the fire extinguishing agent is supplied into the area by the supply part, the fire extinguishing agent is supplied without leaking outside the area, making it possible to extinguish a fire that occurs in the secondary battery.

In short, when the fire extinguishing agent is water, this area into which water is supplied becomes a tank (a submersion tank), and therefore the fire extinguishing device of the present invention can realize a quick fire extinguishing function without requiring a tank for submerging secondary batteries and with a simple structure.

(2) With a configuration in which the enclosure is provided so as to surround four sides and an upper side of the secondary batteries placed on the plate, and a part of the enclosure or the plate has an opening from which the fire extinguishing agent is injected, not only the four sides but also the upper side of the secondary batteries placed on the plate is covered and the fire extinguishing agent is supplied into the area from the opening, so that the area can be filled with the fire extinguishing agent more without leaking the fire extinguishing agent to the outside, and more efficient fire extinguishment can be achieved.

(3) With a configuration in which the fire extinguishing device further includes a pressurizing part that is provided so as to be housed in the area and pressurizes the secondary batteries located in the area toward an outside of the area, the secondary batteries located in the area can be pressurized toward the outside of the area, and therefore it is possible to prevent the secondary battery from swelling in the charge/discharge inspection device and to prevent deformation of the battery case due to the swelling of the secondary battery.

(4) With a configuration in which the fire extinguishing device further includes a container that transports one secondary battery or a plurality of secondary batteries arranged in a thickness direction, wherein the container is placed on the plate, the secondary batteries that are housed in the container and transported can be placed on the plate as they are, and therefore work efficiency in charge and discharge inspections can be improved.

(5) With a configuration in which the fire extinguishing agent is a liquid and the fire extinguishing device further includes a pan provided below the plate for receiving the liquid overflowing from the area, even if the fire extinguishing agent that is a liquid supplied from the supply part overflows from the area, the pan can receive the liquid, and therefore it is possible to increase the efficiency of cleaning operation after extinguishing operation and to prevent the liquid from splashing onto other devices to cause them to break down.

(6) With a configuration in which the charge/discharge inspection device of the present invention includes: these fire extinguishing devices; a probe unit to be connected to a secondary battery; and a lifting and lowering part that lifts or lowers the plate or the probe unit to connect the secondary battery and the probe unit to each other, it is possible to lift or lower the plate or the probe unit to connect the secondary battery and the probe unit or conversely disconnect them, thereby enabling a charge/discharge inspection in a configuration equipped with a fire extinguishing device, and even if a fire occurs in the secondary battery during the charge/discharge inspection, fire extinguishing work can be carried out quickly.

(7) With a configuration in which the charge/discharge inspection device further includes a cooling part that is provided on top of the plate and cools the secondary battery from below, the cooling part can cool the secondary battery placed on the plate from below, and therefore it is possible to prevent the secondary battery from heating up and swelling during the charge/discharge inspection, and prevent deformation of the battery case due to the swelling of the secondary battery.

On the other hand, according to the fire extinguishing method of the present invention, it is possible to obtain the same operational effects as those of the fire extinguishing device of the present invention.

### BRIEF DESCRIPTION OF DRAWINGS

FIG. 1 is a schematic perspective view showing a fire extinguishing device according to an embodiment of the present invention.

FIG. 2 is a schematic perspective view showing the fire extinguishing device according to an embodiment of the present invention.

FIG. 3 is a schematic configuration diagram showing a charge/discharge inspection device according to an embodiment of the present invention.

FIG. 4 is a schematic configuration diagram showing the charge/discharge inspection device according to the embodiment of the present invention.

FIG. 5 is a schematic configuration diagram showing the charge/discharge inspection device according to the embodiment of the present invention.

FIG. 6 is a schematic configuration diagram showing the charge/discharge inspection device according to the embodiment of the present invention.

FIG. 7 is a schematic configuration diagram showing a charge/discharge inspection device according to another embodiment of the present invention.

FIG. 8 is a schematic configuration diagram showing the charge/discharge inspection device according to the other embodiment of the present invention.

### DESCRIPTION OF EMBODIMENTS

Embodiments of the present invention will be described below in detail, but the description of the constituent features described below shows examples (representative examples) of embodiments of the present invention, and the present invention is not limited to the following content unless the spirit thereof is changed.

### Fire Extinguishing Device

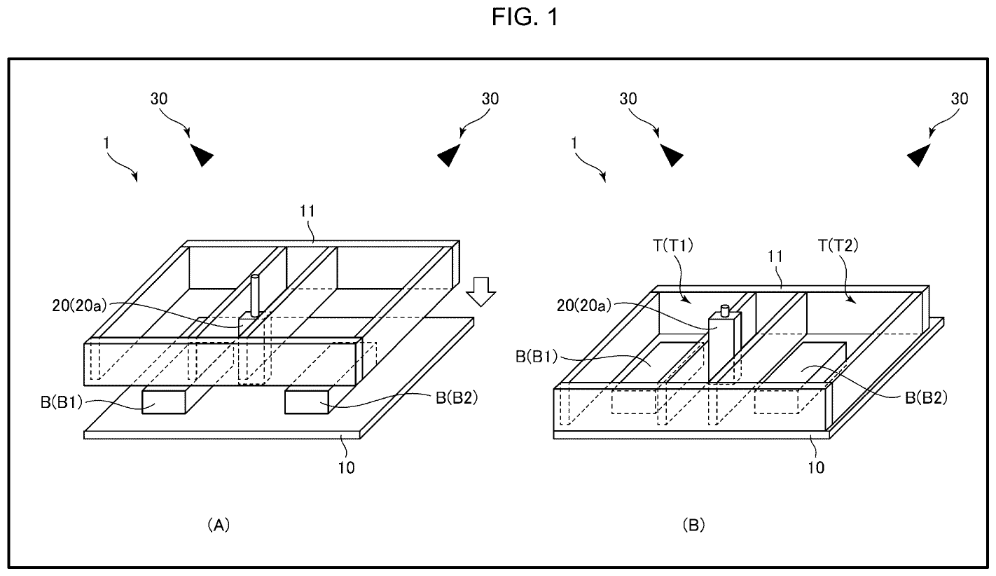

FIG. 1 is a schematic perspective view showing a fire extinguishing device according to an embodiment of the present invention.

A fire extinguishing device 1 has a plate 10 on which secondary batteries B are placed, an enclosure 11 provided to surround the four sides of the secondary batteries B placed on the plate 10, and a lifting and lowering part 20 (20a) that lifts and lowers the enclosure 11 to bring the plate 10 and the enclosure 11 into close contact with each other. Further, the fire extinguishing device 1 also has a supply part 30 that supplies a fire extinguishing agent to areas T formed by the plate 10 and the enclosure 11 (hereinafter simply referred to as “areas”).

The fire extinguishing agent refers to an agent capable of extinguishing a fire that occurs in a secondary battery, such as water. In addition to water, reinforced liquid (potassium carbonate solution), foam (chemical foam, mechanical foam), gas (carbon dioxide, halides), or powder (hydrogencarbonates or the like, phosphates or the like), and the like can be used as the fire extinguishing agent.

One or more secondary batteries are placed on the plate 10. In the example shown in FIG. 1, two secondary batteries B1 and B2 are placed on the plate 10.

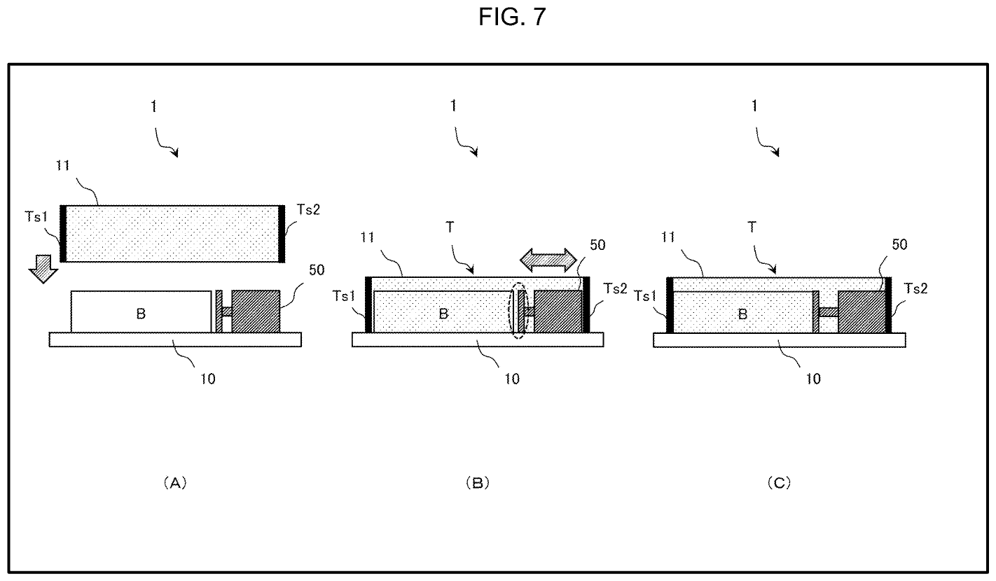

As described above, the enclosure 11 surrounds the four sides of the secondary batteries B and forms the areas T together with the plate 10. The material (e.g., metal or resin), dimensions and the like of the enclosure 11 can be appropriately changed in design as long as it can withstand water pressure (when the fire extinguishing agent is water) or can withstand pressurization by a pressurizing part 50 described later (see FIG. 7).

The lifting and lowering part 20a is a mechanism for lifting and lowering the enclosure 11. A hydraulic cylinder, an air cylinder, or the like can be used for the lifting and lowering part 20a, and there are no particular limitations as long as the mechanism can lift and lower the enclosure 11 while supporting it. Note that the lifting and lowering part 20a shown in FIG. 1 and other figures is merely a schematic diagram for explaining the function of the lifting and lowering part, and detailed description of the configuration is omitted.

Further, as shown in FIG. 1 (A), the plate 10 and the enclosure 11 are provided spaced apart (at a certain distance) in a substantially vertical direction. Therefore, the secondary batteries B can be transported from the lateral direction (horizontal direction) and placed on the plate 10, for example.

Then, from the state shown in FIG. 1 (A), the lifting and lowering part 20a lowers the enclosure 11 (see the arrow in FIG. 1 (A)) to bring the plate 10 and the enclosure 11 into close contact with each other as shown in FIG. 1 (B). By doing so, the plate 10 and the enclosure 11 form the areas T that surround the lower side and four sides of the secondary batteries B.

In the example shown in FIG. 1, the enclosure 11 is provided so as to divide the secondary batteries B1, B2 and the lifting and lowering part 20a into three respective areas, so that in this case, an area T1 in which the secondary battery B1 is contained and an area T2 in which the secondary battery B2 is contained are formed respectively.

Note that in order to improve adhesion, it is desirable to use a material capable of improving adhesion, such as resin or a rubber plate, for the contact surface (contact portion) between the plate 10 and the enclosure 11. At this time, the material may be used on the plate 10 side, on the enclosure 11 side, or on both sides.

Here, as can be seen from FIG. 1 (B), the areas T are formed so as to surround the lower side and four sides of the secondary batteries B, but are open on the upper side. Therefore, when the fire extinguishing agent is water and water is supplied from above by the supply part 30, the water is stored in the area T without leaking to the outside. As a result, the secondary battery B in the area T is submerged, and the fire that occurs in the secondary battery is extinguished.

Further, even in the case of a fire extinguishing agent other than water such as foam (a foam fire extinguishing agent), the formation of such an area T prevents the foam fire extinguishing agent from leaking out, making it possible to more efficiently cover the burning material (the secondary battery) to extinguish the fire by smothering. Note that even when the fire extinguishing agent is gas (carbon dioxide), carbon dioxide has a higher specific gravity than air and therefore tends to remain within the area T, thereby enabling more efficient fire extinguishment.

The supply part 30 can be operated manually or automatically by detecting a fire. For example, since the capacity of the area T is known in advance, when the fire extinguishing agent is water, the supply part 30 can automatically supply water to the extent that the capacity of the area T is filled up.

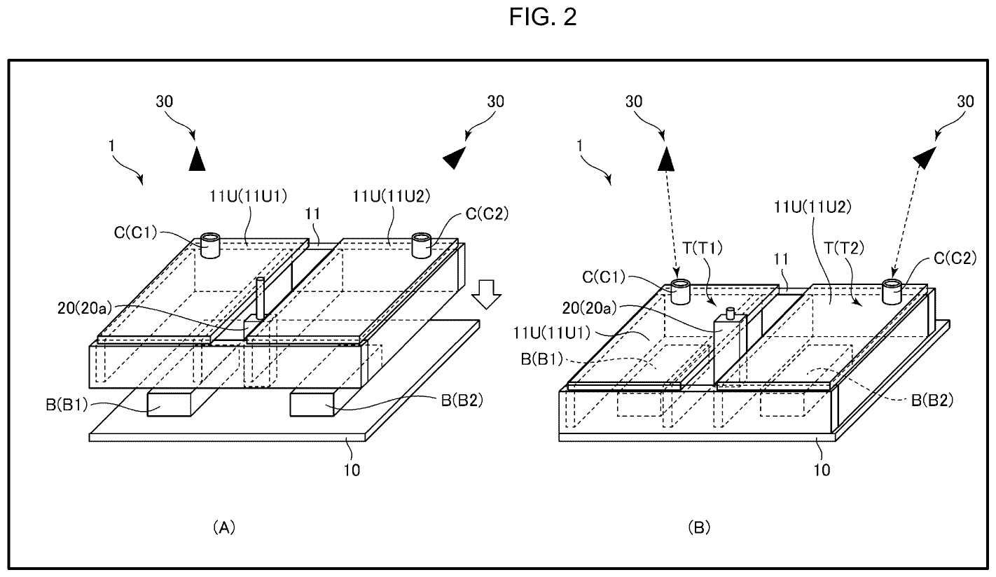

Further, FIG. 2 is also a schematic perspective view showing a fire extinguishing device according to an embodiment of the present invention. The fire extinguishing device 1 shown in FIG. 2 further includes an enclosure 11 that surrounds the four sides of the secondary batteries B and top plates 11U (11U1, 11U2) that cover the upper side of the secondary batteries B. Note that components having the same configurations and operational effects as those already described based on FIG. 1 are given the same reference numerals and detailed description thereof will be omitted.

Here, the top plates 11U have openings C (C1, C2) through which the fire extinguishing agent supplied from the supply part 30 passes (see FIG. 2 (B)). The openings C are, so to speak, inlets for the fire extinguishing agent, and the size, position, shape, and the like thereof can be appropriately changed in design. For example, the openings C may be provided on the enclosure 11 side or on the plate 10 side.

In this manner, the fire extinguishing device 1 shown in FIG. 2 has an enclosure (the enclosure 11 and the top plates 11U) that is provided so as to surround the four sides and the upper side of the secondary batteries B placed on the plate 10 and has the openings C on the upper side. With such a configuration, the area T can be filled with the fire extinguishing agent more, and more efficient fire extinguishment can be achieved.

Note that in this embodiment, a plurality of top plates 11U are provided for the respective areas T1 and T2 (the top plates 11U1, 112), but the top plates 11U may be composed of a single top plate. Further, the enclosure 11 and the top plates 11U may be formed integrally.

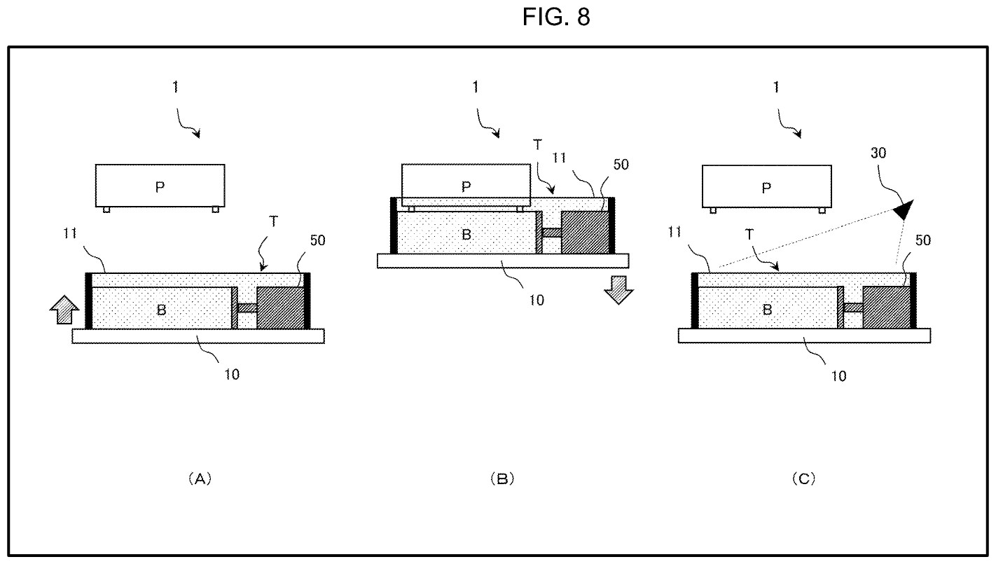

Furthermore, as described later, when a probe unit P is connected to the secondary battery B in the area T (see FIG. 8 (B)), an opening (not shown) for the probe unit can be locally provided in the top plate 11U. That is, in addition to the opening C, an opening through which the probe unit P can be connected to the secondary battery B can be appropriately provided.

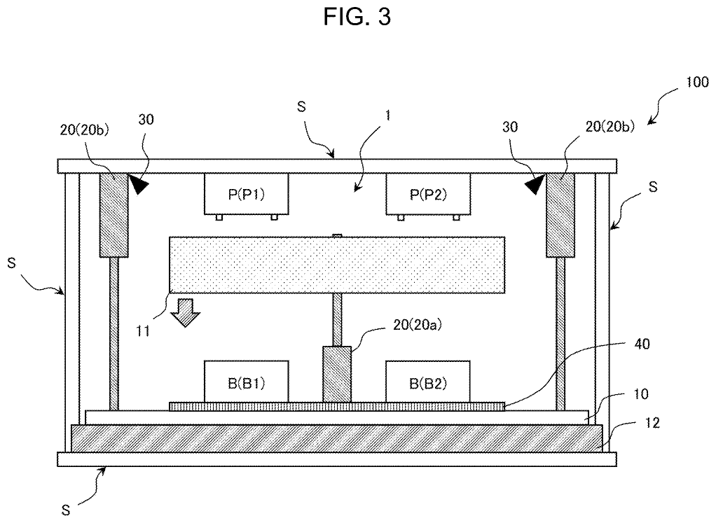

Note that although the fire extinguishing device 1 has a pan 12 (see FIG. 3) for receiving water overflowing from the area T, the pressurizing part 50 (see FIG. 7), and the like in addition to the above-described components, they will be described in detail later.

[Charge/Discharge Inspection Device]

FIGS. 3 to 6 are schematic configuration diagrams showing a charge/discharge inspection device according to the embodiment of the present invention. The charge/discharge inspection device 100 includes the fire extinguishing device 1 described above. Note that components having the same configurations and operational effects as those already described are given the same reference numerals and detailed description thereof will be omitted.

Note that in the following description, it is assumed that the fire extinguishing agent is water and the supply part 30 supplies water. At the same time, since water is stored in the areas T, the areas T (areas T1, T2) will be referred to as “submersion tanks T (submersion tanks T1, T2)” for description.

As shown in FIG. 3, the charge/discharge inspection device 100 is composed of a support member S, and has probe units P, the pan 12, a lifting and lowering part 20 (20b), and a cooling part 40 in addition to the fire extinguishing device 1.

The probe unit P is connected (attached) to a secondary battery to be inspected in a charge/discharge inspection. Specifically, the electrode (positive electrode) of the secondary battery B contacts the positive probe of the probe unit P, and the electrode (negative electrode) of the secondary battery B contacts the negative probe of the probe unit P. In addition, power is supplied to the secondary battery B via the probe unit P from a charge/discharge power source (not shown) connected by a cable (not shown).

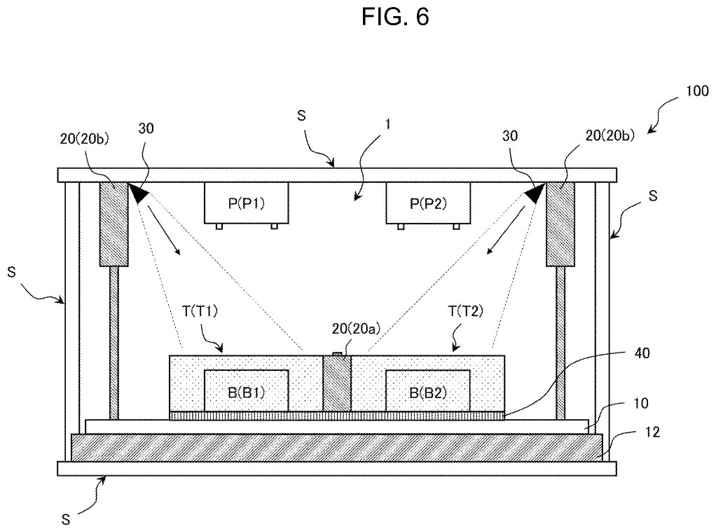

Further, the pan 12 is for receiving water overflowing from the submersion tank T when the supply part 30 supplies water to the submersion tank T to store the water therein (see FIG. 6). In the example shown in FIG. 3, the pan 12 is provided below the plate 10, but as long as it can receive water overflowing from the submersion tank T, the position at which the pan is provided, the width and depth of the pan, the material of the pan, the drainage treatment function of the pan, or the like can be appropriately changed in design.

Further, the cooling part 40 is provided on top of the plate 10 and cools the secondary batteries B from below. For example, a cooling fan that blows cool air to the secondary batteries B can be used for the cooling part 40.

Note that the charge/discharge inspection device 100 has a container (not shown) for transporting one secondary battery or a plurality of secondary batteries arranged in the thickness direction. Therefore, the secondary batteries that are housed in a container and transported can be placed on the plate 10 as they are.

In addition, openings can be provided on the bottom surface of the container. Therefore, for example, by sending cool air toward the openings from the cooling part 40, the secondary batteries B housed in the container can be cooled from below.

Further, the lifting and lowering part 20b is a mechanism for lifting and lowering the plate 10. A hydraulic cylinder, an air cylinder, or the like can be used for the lifting and lowering part 20b, and there are no particular limitations as long as the mechanism can lift and lower the plate 10 and the secondary batteries B placed on the plate 10 while supporting them.

Note that in the description of the lifting and lowering part 20 in this embodiment, it is assumed for the sake of convenience that the lifting and lowering part 20a lifts and lowers the enclosure 11 and the lifting and lowering part 20b lifts and lowers the plate 10.

### Operation of Charge/Discharge Inspection Device

The operation of the charge/discharge inspection device according to this embodiment will be described below based on FIGS. 3 to 6.

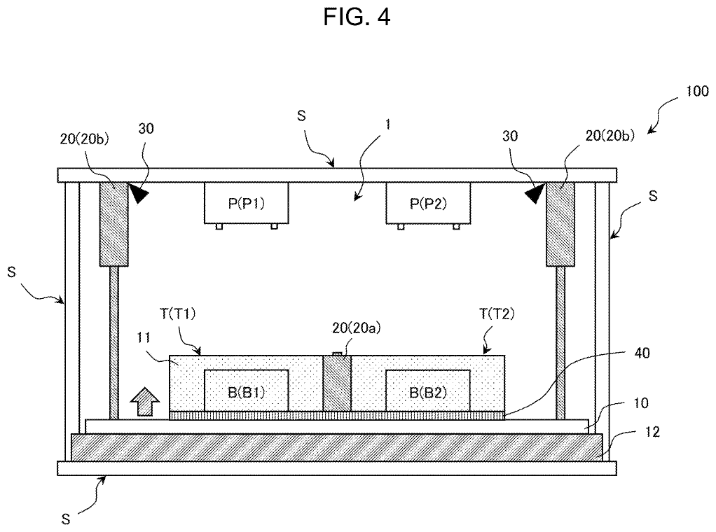

First, from the state where the secondary batteries B are placed on the plate 10, the lifting and lowering part 20a lowers the enclosure 11 in the direction of the arrow shown in FIG. 3. When the lifting and lowering part 20a lowers the enclosure 11, the plate 10 and the enclosure 11 come into close contact with each other to form the submersion tanks T surrounding the secondary batteries B as shown in FIG. 4.

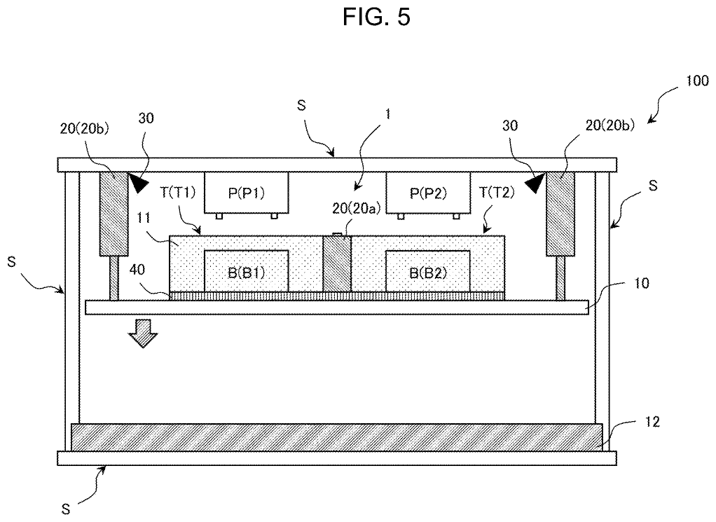

Next, the lifting and lowering part 20b lifts the plate 10 in the direction of the arrow shown in FIG. 4. When the lifting and lowering part 20b lifts the plate 10, the plate 10, the secondary batteries B placed on the plate 10, the lifting and lowering part 20a, and the like are also lifted as shown in FIG. 5.

Then, a charge/discharge inspection is performed with the submersion tanks T formed. For convenience of explanation, the probe units P and the secondary batteries B are not connected in FIG. 5, but the lifting and lowering part 20b can lift the plate 10 to the position where the probe units P and the secondary batteries B are connected.

Further, the position at which the enclosure 11 is supported by the lifting and lowering part 20a as shown in FIG. 3 can be made higher. For example, when the lifting and lowering part 20b lifts the plate 10 to form the submersion tanks T, the lifting and lowering part 20a can support the enclosure 11 at the position where the probe units P and the secondary batteries B are connected.

Here, if a fire occurs in a secondary battery B during the charge/discharge inspection, the lifting and lowering part 20b lowers the plate 10 in the direction of the arrow shown in FIG. 5.

Thereafter, as shown in FIG. 6, water is supplied by the supply part 30, so that water is stored in the submersion tank T, and the secondary battery B in the submersion tank T is submerged to extinguish the fire.

As described above, since the submersion tanks T are formed by the fire extinguishing device 1 when a charge/discharge inspection is performed, there is no need to previously provide tanks for submerging secondary batteries, and the structure can be simplified. Further, the plate 10 is lowered to move the secondary batteries B and water is supplied to the submersion tanks T by the supply part 30, thereby enabling a quick fire extinguishing operation even during a charge/discharge inspection.

Further, as described above, since a submersion tank T can be formed for each secondary battery B (see, e.g., the submersion tanks T1, T2 in FIG. 1), the supply part 30 can also supply water only to a submersion tank T that houses a secondary battery B in which a fire occurs. This makes it possible to effectively utilize a secondary battery B in which no fire occurs without submerging it.

Note that if no fire occurs in the charge/discharge inspection, for example, the lifting and lowering part 20a continues to support the enclosure 11 at the original position (the position shown in FIG. 2), and the lifting and lowering part 20b lowers the plate 10 and the secondary batteries B placed on the plate 10 to return the state to the original state (the state shown in FIG. 3), so that the charge/discharge inspection can be completed.

### Pressurizing Part

FIGS. 7 and 8 are schematic configuration diagrams showing a charge/discharge inspection device according to another embodiment of the present invention.

Specifically, the fire extinguishing device 1 is configured to include the pressurizing part 50. Note that since FIGS. 7 and 8 are primarily for explaining the pressurizing part 50, the depiction of some components, such as the depiction of the lifting and lowering part for lifting and lowering the plate 10 and the enclosure 11 and the depiction of the cooling part 40 are omitted.

The fire extinguishing device 1 has the pressurizing part 50 on the plate 10 (see FIG. 7 (A)). Here, when the enclosure 11 is lowered by the lifting and lowering part 20a (see FIG. 1) as described above, a submersion tank T is formed as shown in FIG. 7 (B). In addition, the pressurizing part 50 is housed in this submersion tank T together with the secondary battery B. That is, the pressurizing part 50 is provided on the plate 10 so as to be housed in the submersion tank T (see FIG. 7 (A)).

After the submersion tank T is formed, the pressurizing part 50 pressurizes the secondary battery B in the submersion tank T toward the outside of the submersion tank T. In the example shown in FIG. 7 (B), the pressurizing part 50 extends horizontally (see the arrow), so that one end thereof comes into contact with the secondary battery B (see the dotted frame) to pressurize the secondary battery B toward the outside of the submersion tank T.

By doing so, the secondary battery B is pressed tightly against the wall surface Ts1 of the enclosure 11 as shown in FIG. 7 (C). On the other hand, while the pressurizing part 50 is pressurizing the secondary battery B, the other end thereof is also tightly pressed against the wall surface Ts2 located in the opposite direction to the wall surface Ts1.

In this manner, by pressurizing the secondary battery B using the pressurizing part 50, it is possible to prevent the secondary battery B from swelling in the charge/discharge inspection device and to prevent deformation of the battery case due to the swelling of the secondary battery B.

Besides, if the secondary battery is in a pressurized state, it is possible to mitigate the impact when an abnormality occurs in the secondary battery to cause explosion, for example. Further, by mitigating such impact, it is possible to prevent secondary damage to the container or the other normal secondary batteries.

Thereafter, when the plate 10 is lifted (see the arrow in FIG. 8 (A)) by the lifting and lowering part 20b as described above (see FIG. 3), the secondary battery B is connected to the probe unit P (see FIG. 8 (B)).

In addition, if a fire occurs in the charge/discharge inspection, the plate 10 can be lowered by the lifting and lowering part 20b (see FIG. 3) to be disconnected from the probe unit P, and then the fire can be extinguished by the supply part 30 (see FIG. 8 (C)).

The present embodiments described above are merely examples, and the configurations of the fire extinguishing device 1 and the charge/discharge inspection device 100 can be appropriately changed in design without departing from the spirit of the present invention.

For example, a hydraulic cylinder, an air cylinder, or other mechanisms can be used for the pressurizing part 50 as long as they can pressurize the secondary battery B in the submersion tank T toward the outside of the submersion tank T.

Further, since there is a gap between the secondary battery B and the enclosure 11 as shown in FIG. 1, the direction of pressurization can be designed as desired. For example, in the example shown in FIG. 7, the pressurizing part 50 may be provided on the plate 10 so as to pressurize the secondary battery B from the near side toward the far side.

Furthermore, regarding the configuration of the lifting and lowering parts 20 (20a, 20b), the number of lifting and lowering parts, the positions at which the lifting and lowering parts are provided, or the configuration of the lifting and lowering parts themselves can be appropriately changed in design as long as they can achieve the following functions.

In order to form the submersion tank,
(1) the enclosure is lowered to be brought into close contact with the plate located below, and
(2) the plate is lifted to be brought into close contact with the enclosure located above.

In order to perform a charge/discharge inspection,
(1) the enclosure and the plate are lifted to connect the secondary battery and the probe unit to each other,
(2) the enclosure and the plate are lowered to disconnect the secondary battery and the probe unit from each other,
(3) the probe unit is lowered to connect the secondary battery and the probe unit to each other, and
(4) the probe unit is lifted to disconnect the secondary battery and the probe unit from each other.

Besides, in the charge/discharge inspection in these embodiments, the probe unit is connected to the secondary battery and power is supplied from the charge/discharge power source to the secondary battery via the probe unit, but the fire extinguishing device 1 and the charge/discharge inspection device 100 can use various inspection methods such as aging (applying voltage to charge the battery and then discharging it over several days).

### INDUSTRIAL APPLICABILITY

The present invention is industrially useful because it can be used as a fire extinguishing device capable of realizing a quick fire extinguishing function without requiring a tank for submerging secondary batteries and with a simple structure, a charge/discharge inspection device having the same, and a fire extinguishing method.

### REFERENCE SIGNS LIST

1 fire extinguishing device
10 plate
11 enclosure
11U, 11U1, 11U2 top plate
12 pan
20 lifting and lowering part
20a lifting and lowering part (for enclosure)
20b lifting and lowering part (for plate)
30 supply part
40 cooling part
50 pressurizing part
100 charge/discharge inspection device
T, T1, T2 area (submersion tank)
Ts1, Ts2 wall surface
B, B1, B2 secondary battery
P, P1, P2 probe unit
C, C1, C2 opening
S support member

1. A fire extinguishing device comprising:
a plate on which one or more secondary batteries are placed;
an enclosure provided so as to surround four sides of the secondary batteries placed on the plate;
a lifting and lowering part that lifts or lowers the plate or the enclosure to bring the plate and the enclosure into close contact with each other; and
a supply part that supplies a fire extinguishing agent to an area formed by the plate and the enclosure.

2. The fire extinguishing device according to claim 1, wherein
the enclosure is provided so as to surround four sides and an upper side of the secondary batteries placed on the plate, and
a part of the enclosure or the plate has an opening from which the fire extinguishing agent is injected.

3. The fire extinguishing device according to claim 1, further comprising:
a pressurizing part that is provided so as to be housed in the area and pressurizes the secondary batteries located in the area toward an outside of the area.

4. The fire extinguishing device according to claim 1, further comprising:
a container that transports one secondary battery or a plurality of secondary batteries arranged in a thickness direction, wherein the container is placed on the plate.

5. The fire extinguishing device according to claim 1,
wherein the fire extinguishing agent is a liquid,
the fire extinguishing device further comprising:
a pan provided below the plate for receiving the liquid overflowing from the area.

6. A charge/discharge inspection device comprising:
the fire extinguishing device according to claim 1;
a probe unit to be connected to a secondary battery; and
a lifting and lowering part that lifts or lowers the plate or the probe unit to connect the secondary battery and the probe unit to each other.

7. The charge/discharge inspection device according to claim 6, further comprising:
a cooling part that is provided on top of the plate and cools the secondary battery from below.

8. A fire extinguishing method comprising:
a step of placing one or more secondary batteries on a plate;
a step of lowering an enclosure provided so as to surround four sides of the secondary batteries placed on the plate or lifting the plate to bring the plate and the enclosure into close contact with each other; and
a step of supplying a fire extinguishing agent from an opening to an area formed by the plate and the enclosure.
